(19) United States
(12) Patent Application Publication
(10) Pub. No.: US 2008/0264679 A1
(43) Pub. Date: Oct. 30, 2008

(54) Printed Circuit Board With Combined Digital and High Frequency Applications

(75) Inventor: Johan Sandwall, Floda (SE)

Correspondence Address: ERICSSON INC., 6300 LEGACY DRIVE, M/S EVR 1-C-11, PLANO, TX, 75024, US

(73) Assignee: TELEFONAKTIEBOLAGET LM ERICSSON (PUBL), Stockholm (SE)

(21) Appl. No.: 11/720,448

(22) PCT Filed: Nov. 30, 2004
(86) PCT No.: PCT/SE04/01761

§ 371 Date: May 30, 2007

(51) Int. Cl. H05K 1/03

(52) U.S. Cl. 174/255

(57) ABSTRACT

The invention discloses a PCB (100, 400) with first and second main surfaces (110, 130), the PCB also having a first height, h, said two surfaces and height together defining the volume of the PCB. The PCB comprises layers (430, 434, 438) of a first supporting laminate material, layers (440, 431, 433, 435, 437, 439) of a first conducting material and layers (432, 436) of a first prepreg, said first materials and prepreg having respective dielectrical constants and dissipation factors. In the PCB, a sub-volume of the PCB defined by a sub-area (120) within the first main surface and a sub-height (h′) within said first height together comprise a sub-PCB (320) which comprises at least one layer (330, 334) of a second supporting laminate material, said second laminate material differing from the first laminate material with regard to at least one of the factors dielectrical constant and dissipation factor.

### TECHNICAL FIELD

The present invention discloses a printed circuit board, a PCB, which has a first main surface and an opposing second main surface, as well as a first height, h, where the height defines the shortest distance from the first main surface to the second main surface.

The two main surfaces and the height together define the volume of the PCB, and the PCB comprises layers of a first supporting laminate material, as well as layers of a first conducting material and layers of a first so called prepreg.

The first materials and prepreg have respective dielectrical constants and dissipation factors.

### BACKGROUND ART

Printed Circuit Boards, PCB:s, are often designed for either digital or high frequency, HF, applications. These two application fields often need PCB materials which have quite different properties, i.e. a material which will perform well with digital technology will not be optimal for HF-applications and vice versa.

Thus, when a PCB is designed which will be used both for digital and HF-components, a compromise has to be made when it comes to choice of material, which will lead to a material being chosen which will be a compromise for both fields of technology with regard to its properties.

### DISCLOSURE OF THE INVENTION

As shown above, there is a need for a PCB which can perform optimally in different fields of technology or frequencies.

This need is addressed by the present invention in that it discloses a printed circuit board, a PCB, with a first main surface and an opposing second main surface, which PCB also having a first height, h. The height h is the shortest distance from the first main surface to the second main surface, and the two main surfaces and height together define the volume of the PCB.

The PCB of the invention comprises layers of a first supporting laminate material as well as layers of a first conducting material and layers of a first so called prepreg. The first materials and the prepreg have respective dielectrical constants and dissipation factors, and in the PCB there is a sub-volume of the PCB defined by a sub-area within the first main surface and a sub-height within the first height, which together comprise a sub-PCB within the PCB.

The sub-PCB comprises at least one layer of a second supporting laminate material, which second laminate material differs from the first laminate material with regard to at least one of the factors dielectrical constant and dissipation factor.

The sub-PCB may also comprise at least one layer of a second conducting material and/or at least one layer of a second so called prepreg with respective dielectrical constants, at least one of which differs from the dielectrical constant of the corresponding first material in the PCB.

The invention also discloses a method for manufacturing the PCB described above.

### BRIEF DESCRIPTION OF THE DRAWINGS

The invention will be describe din closer detail with reference to the appended drawings, in which:

FIG. 1 shows a plane view from above of a PCB of the invention, and

FIG. 2 shows the PCB of FIG. 1 seen from the direction of the arrow d, and

FIG. 3 shows a sub-PCB of the invention, and

FIG. 4 shows the PCB of FIG. 1 in cross section along the line IV-IV, and

FIG. 5 shows a flow chart of some major steps in the production of a PCB of the invention.

### EMBODIMENTS OF THE INVENTION

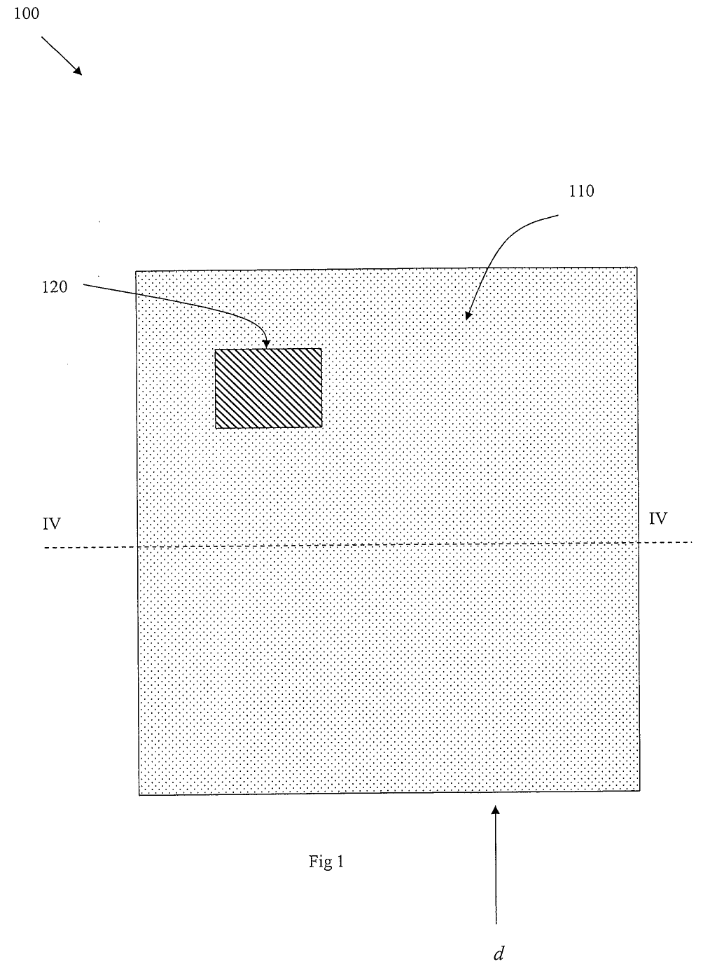

FIG. 1 shows a plan view from above of a Printed Circuit Board, a PCB, 100 of the invention. As can be seen, the PCB 100 has a first main area 110, which is essentially rectangular in shape, although this shape can be varied within the scope of the invention.

In addition to the first main area or surface 110, the PCB also comprises a sub-area 120 within the first main area 110. The function of the sub-area will be explained in more detail later on in this description.

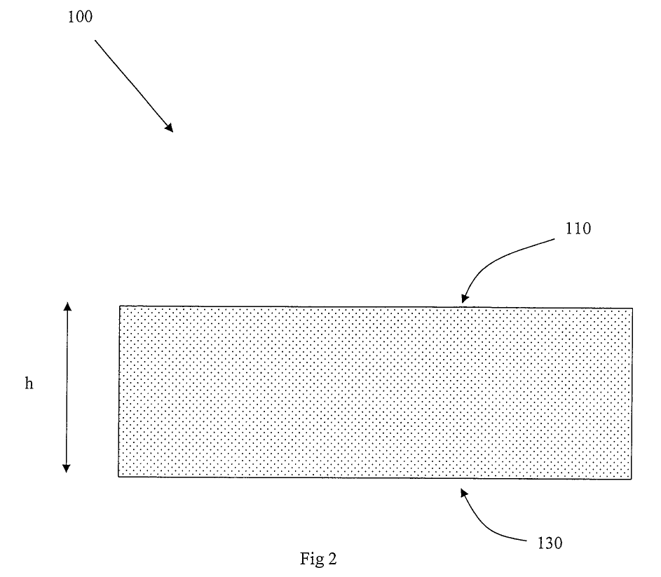

FIG. 2 is a view from the side of the PCB 100, seen from the direction indicated by the arrow d in FIG. 1. As can be seen in this drawing, the PCB 100 also comprises a second main surface 130, which is opposite the first main surface 110. FIG. 2 also shows that the PCB 100 has a height h, where the height h defines the shortest distance between the two main surfaces 110, 130.

The PCB 100 of the invention comprises layers of a first supporting laminate material, suitably but not necessarily so called FR4, interwoven with layers of a first conducting material such as for example copper. In addition to these material layers, the PCB 100 also comprises layers of a first so called prepreg.

The material referred to consistently in this text as “prepreg” is used as a bonding material to fix rigid laminates together and to fill spacing between, for example, layers inside Printed Circuit Boards so that air pockets are essentially eliminated. Prepreg has a semi-cured chemistry, and can therefore be formed under special pre-defined combinations of heat, pressure and vacuum.

Once the prepreg chemistry has cured completely, it is fixed and will stay in that shape.

As an alternative to prepreg as bonding material, so called bonding films can also be used to fix different material layers to each other and to fill spaces or cavities between material layers inside Printed Assembly Boards. Bonding films are also formed by heat, pressure and vacuum, but can be melted several times.

Said first materials, i.e. the supporting laminate and the conducting material, as well as the first prepreg have respective dielectrical constants ∈ and loss factors, the latter also being known as the dissipation factor of the material.

The sub-area 120 shown in FIG. 1, together with a defined sub-height which extends into the PCB, defines a sub-volume of the PCB. This sub-volume of the PCB also comprises layers of a second supporting laminate material, where the second laminate material has a dielectrical constant which is different from that of the first laminate material.

Preferably, but not necessarily, the dissipation factor of the second supporting laminate material of the sub-PCB is also different from that of the first laminate material, i.e. larger or smaller.

In a preferred embodiment, as will be shown below, the sub-PCB also comprises layers of a second conducting material and layers of a second so called prepreg, each having respective dielectrical constants, at least one of which differs from the dielectrical constant of the corresponding first material in the PCB.

In addition, in the same preferred embodiment of the invention, the second conducting material and second so called prepreg of the sub-PCB have respective dissipation factors, at least one of which differs from the dissipation factor of the corresponding first material in the PCB.

As will be understood, the differences between the materials in the sub-PCB and the corresponding materials in the PCB can be varied as desired, i.e. the dielectrical constants and the dissipation factors may vary or coincide between the various layers, as is deemed appropriate by the application for which the PCB is made.

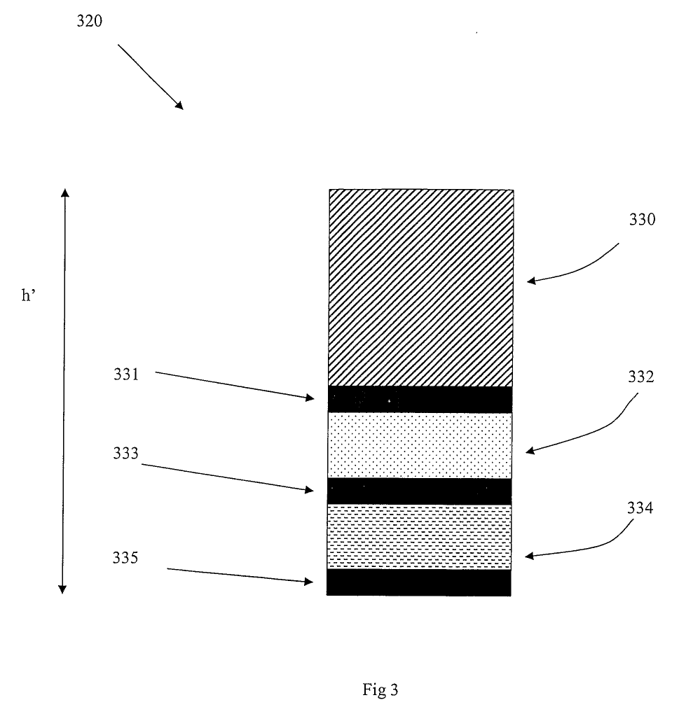

FIG. 3 shows a sub-PCB 320 of the invention seen from the side. As shown in the drawing, the sub-PCB 320 comprises a number of layers of a conducting material 331, 333, 335. There is also a first layer 334 of a non-conducting laminate material, as well as a second layer 330 of a non-conducting laminate material. The two laminate layers 330, 334, may be made of the same kind of laminate material or of different materials, i.e. materials which have different dielectrical constants and/or different dissipation factors.

On either side the first laminate layer 334 there is arranged one of said layers 335, 333, of a conducting material. It should be pointed out here that the number of conducting layers arranged on either side of the laminate layers are merely examples and can be varied freely, i.e. there can be a conducting layer on one or on both sides of the laminate layers. Also, there may be laminate layers which have no conducting materials on either of its sides.

In between the layers of laminate 330, 334, with their respective layers 331, 333, 335, of conducting material there is arranged a layer of so called prepreg 332.

As shown in FIG. 3, the sub-PCB 320 has an extension h′ in the direction in which the layers are arranged, and the sub-PCB 320 will later be arranged so that its height h′ essentially coincides with the extension of an opening in the PCB.

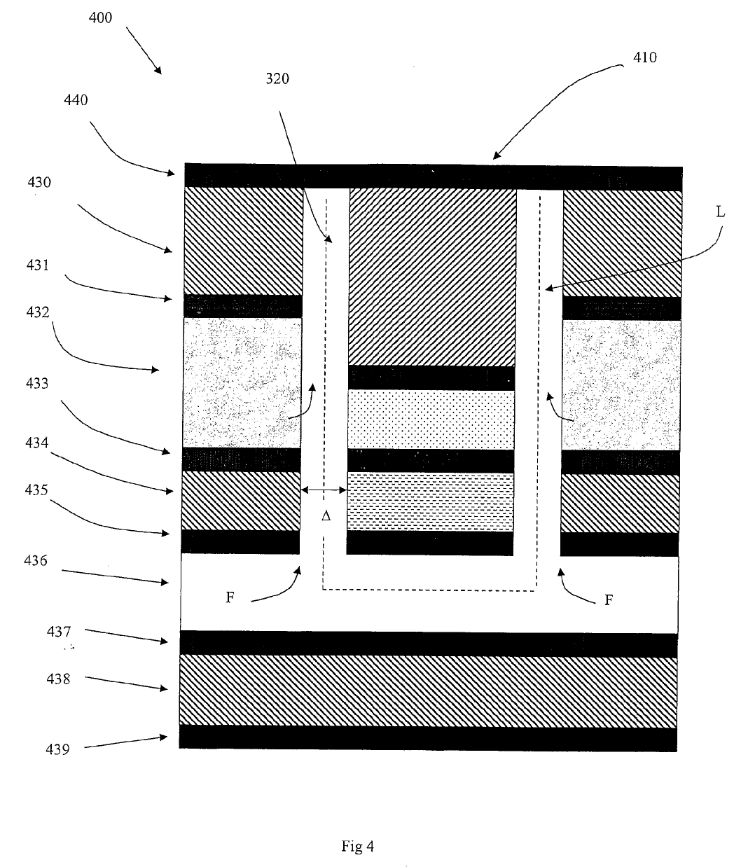

The sub-PCB is arranged in a recession or opening in the PCB 100 so that the upper surface of the sub-PCB essentially coincides with the upper main surface of the PCB. The sub-PCB 320 arranged in a PCB 400 is shown in FIG. 4. The PCB 400 is shown in FIG. 4 in a cross section along the dashed line IV-IV in FIG. 1. In order to enhance the understanding of FIG. 4, the sub-PCB is shown with a dotted line L, as well as being referenced to as 320 in the drawing.

It can be pointed out here that although the sub-PCB is shown in, for example, FIG. 1, as being essentially rectangular in shape, the shape of the sub-PCB can be varied in a variety of ways within the scope of the invention. The sub-PCB can, for example, be round or oval.

Returning now to FIG. 4, the hole or opening on the PCB in which the sub-PCB is arranged will naturally conform to the outer form of the sub-PCB.

As shown, the PCB (not including the sub-PCB) comprises a number of laminate layers 430, 424, 438, which on one or both of their respective sides have layers 431, 433, 435, 437, 439, 440, of a conducting material.

The layers in the PCB are arranged so that a layer of laminate 430, 438, is adjacent to each of the main surfaces, and in this particular embodiment, both of these laminate layers have a layer of a conducting material on that side which faces outwards, i.e. the layers 439 and 440.

Interlaced with the laminate layers with their respective conducting patterns there are arranged layers 432 and 436 of so called prepreg.

As can be seen in FIG. 4, the upper surface of the sub-PCB 120 is arranged to essentially coincide with the upper surface of the main PCB. If the respective upper surfaces comprise a layer of laminate 430, 330, it is these which will essentially coincide, and if there is arranged a layer of conducting material outermost on each body, PCB and sub-PCB, it is these layers which will be arranged to coincide.

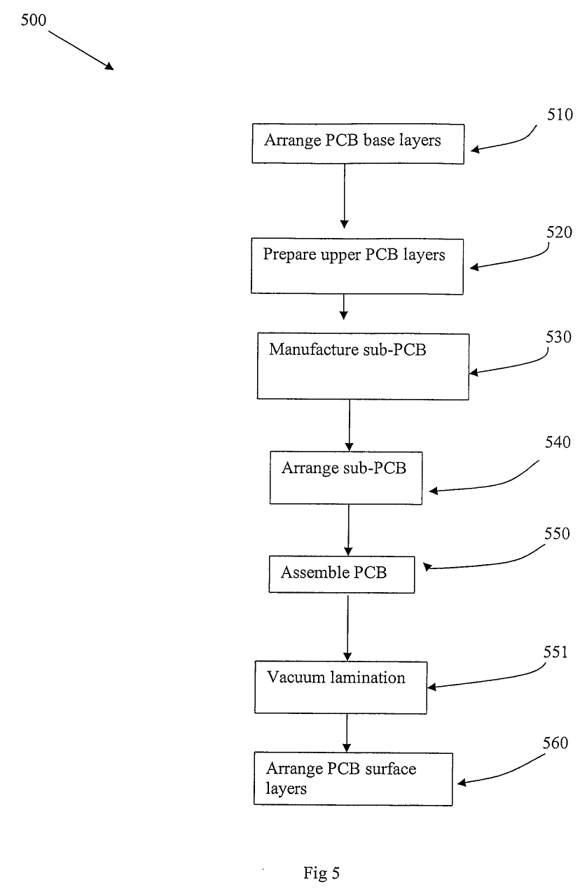

FIG. 5 is a flow chart which shows some of the major steps in producing a PCB 100 of the invention. Said production will now be described with reference to FIG. 5. It should be pointed out that the flow chart and the description of the steps of the flow chart only comprise some of the major steps in the production of the PCB. It should also be pointed out that the number of layers shown and described in the drawings and in this text are mere examples, those skilled in the field will realize that the number of layers can be varied in a wide variety of ways.

As an initial step, box 510 of the flow chart, the base layers of the future PCB 400 are arranged. In this case, the layers concerned are bottom laminate layer 438 with a copper layer 437, 439, on one or both of its sides. The arranging of these layers 437, 438, 439, comprises the preparation of a laminate layer which has the desired size, which can be the size of the future PCB, or as an alternative, a multiple of the size of the future PCB, if several PCB:s are to be manufactured at once. On one or both side of this laminate layer, circuit patterns of a conducting material are arranged, which is done by one of a number of well known conventional methods, and will thus not be described here.

The next box, 520, shows that the upper layers of the PCB are prepared. In this case, the layers concerned are the laminate layers 434 and 430, with an intermediate layer 432 of prepreg, and layers of conducting circuit patterns 435, 433, 431, on—in this case—both sides of the laminate layers 430, 434.

The preparation of the upper layers of the PCB involves giving them the right outer sizes, which in this case, as in the case above, can be the size of one or more PCB:s. In addition, the layers are also given an opening for the sub-PCB, i.e. an opening which corresponds to the outer measurements of the sub-PCB. Suitably, the opening exceeds the size of the sub-PCB by a small amount Δ, preferably about 1-5%.

The next step, block 530 involves manufacturing the sub-PCB 320. Again, it will be understood that the number of layers and their respective arrangement can be varied, the sub-PCB shown and described is merely an example to illustrate a principle.

The layers of the sub-PCB 320 have been described previously, and will thus not be described again. However, the layers are arranged in the desired fashion, and are then processed to become the sub-PCB by means of a so called vacuum lamination oven, in which the layers are pressed against each other and subjected to a temperature which will cause the prepreg (or bonding film, as the case may be) to first become liquid, and to then cure and fix the layers of the sub-PCB to each other.

As a next step, block 540, the sub-PCB is arranged on the base layers of the PCB which were prepared in step 510. Following this, block 550, the rest of the PCB is then assembled “around” the sub-PCB, i.e. the upper layers which were prepared in step 520 are arranged on the base layers, with the sub-PCB in the respective openings of the upper layers.

When the entire PCB, including the sub-PCB, is assembled, the PCB is then subjected to a vacuum lamination process of the kind described previously. This process will cause the prepreg layers 432, 436, to become liquid, and flow into any cavities or spaces in the PCB.

The reason for leaving a space Δ between the upper layers of the PCB and the sub-PCB will now become apparent: during the vacuum lamination process, the layers of the PCB are subjected to pressure from the directions defined by the main surfaces of the PCB

Thus, some of the prepreg will flow into the space Δ and fill this space, thus causing the sub-PCB 320 to be stably arranged in the PCB 400 when the prepreg hardens.

Accordingly, the PCB is removed from the vacuum lamination oven and the prepreg hardens.

The final step (apart from, possibly, making one or both of the main surfaces smooth after the lamination process) is to arrange a layer 439, 440, of conducting material on one or both of the main surfaces of the PCB. This will not be described in detail here, since it is a well known technology, and can be carried out in a variety of ways. However, one possible way of doing it is to use laminate materials, in both the top layer of the sub-PCB and the upper layers of the PCB which are already covered on one side with a thin layer of copper. This thin layer is then covered with an additional thin layer of copper, in which circuit patterns are created in a desired manner, using, for example, photolithographic methods.

The invention is not limited to the examples of embodiments shown above, but can be varied freely within the scope of the appended claims. For example, the outer shape of the PCB or of the sub-PCB may be varied in an essentially arbitrary manner. The outer shape of both has been shown as rectangular for both, but one or both may be given alternate shapes, such as for example, round.

As an obvious alternative to that which has been described in conjunction with blocks 540 and 550 above, the sub-PCB may be positioned in the PCB after the upper PCB layers have been arranged on the base layers. In this case, the hole or opening in the upper layers for accommodating the sub-PCB may also be arranged in the upper layers after said layers have been arranged on the base layers.

Finally, as has been mentioned previously, the number of layers in the PCB and the sub-PCB may be varied more or less freely. Additionally, the supporting layers used in the sub-PCB may also differ from each other with regard to electrical properties, such as dielectrical constant and dissipation factor. The same is true of the conducting materials used in the sub-PCB, as well as the layers of prepreg or bonding film, if more than one such layer is used in the sub-PCB.

The same is true of the layers used in the “main” PCB, i.e. those parts which are not part of the sub-PCB: the layers in the main PCB may have the same or different dielectrical constants and/or dissipation factors.

1. A printed circuit board, a PCB, with a first main surface and an opposing second main surface, the PCB also having a first height, h, i.e. the shortest distance from the first main surface to the second main surface, said two surfaces and height together defining the volume of the PCB, the PCB comprising layers of a first supporting laminate material, layers of a first conducting material and layers, of a first so called prepreg or a first bonding film, said first materials and prepreg having respective dielectrical constants and dissipation factors the PCB being characterized in that a sub-volume of the PCB defined by a sub-area within the first main surface and a sub-height (h′) within said first height together comprise a sub-PCB (within the PCB, said sub-PCB comprising at least one layer of a second supporting laminate material, said second laminate material differing from the first laminate material with regard to at least one of the factors dielectrical constant and dissipation factor.

2. The PCB of claim 1, in which the sub-PCB also comprises at least one layer of a second conducting material, which differs from the first conducting material with regard to at least one of the factors dielectrical constant and dissipation factor.

3. The PCB of claim 1, in which the sub-PCB also comprises at least one layer of a second so called prepreg or a second bonding film, which differs from the corresponding first material with regard to at least one of the factors dielectrical constants and respective dissipation factors.

4. A method for manufacturing a PCB, said PCB having a first main surface and an opposing second main surface the PCB also having a first height, h, i.e. the shortest distance from the first main surface to the second main surface, said two surfaces and height together defining the volume of the PCB, the method comprising:
arranging base layers for the PCB, including at least one layer of a first supporting laminate,
preparing upper layers for the PCB, including at least one layer of supporting laminate,
arranging at least one layer of prepreg or bonding film,
arranging at least one layer of a first conducting material,
said first materials and prepreg or bonding film having respective dielectrical constants and dissipation factors, the method being characterized in that it comprises:
manufacturing a sub-PCB with a sub-height (h′), with at least one layer of a second supporting laminate material, said second laminate material differing from the first laminate material with regard to at least one of the factors dielectrical constant and dissipation factor,
having a dielectrical constant which is,
arranging the sub-PCB (in the PCB, fixing the sub-PCB in the PCB.

5. The method of claim 4, additionally comprising giving the sub-PCB at least one layer of a second conducting material which differs from the first conducting material with regard to at least one of the factors dielectrical constant and dissipation factor.

6. The method of claim 4, additionally comprising giving the sub-PCB at least one layer of a second so called prepreg or a second bonding film, which differs from the corresponding first material with regard to at least one of the factors dielectrical constants and respective dissipation factors.
